(19) United States
(12) Patent Application Publication
(10) Pub. No.: US 2011/0154700 A1
(43) Pub. Date: Jun. 30, 2011

(54) ILLUMINATED SIGN FOR ELECTRONIC DEVICES

(76) Inventor: CHRIS IOAKIMIDIS, Burlington, MA (US)

(21) Appl. No.: 12/981,255

(22) Filed: Dec. 29, 2010

Related U.S. Application Data
(60) Provisional application No. 61/290,503, filed on Dec. 29, 2009.

(51) Int. Cl. G09F 13/00; H05K 13/04

(52) U.S. Cl. 40/541; 29/825

(57) ABSTRACT

An illuminated sign for various electronic devices comprising: a plurality of LED lights on a first side, where the lights provide a customized display; an adhesive backing on a second side, where the backing provides a means to attach the sign to an external panel; a means to supply power to the plurality of LED lights; and an internet connection, where a user submits design requirements prior to installing the sign. The customized display may include at least one of a sign depicting text, a logo or other artistic design. In one particular embodiment, the input means for customizing the sign are accessible via an internet connection.

### CROSS REFERENCE TO OTHER APPLICATIONS

This application claims priority to U.S. Provisional Application Ser. No. 61/290,503 filed on Dec. 29, 2009.

### BACKGROUND OF THE INVENTION

1. Field of Invention

The present invention relates to an illuminated sign for various electronic devices.

2. Description of Related Art

Many electronic devices such Netbooks, Tablets, E-readers, E-reader/Tablets, Desktops, Phones, PDA's, Smart phones, MP3 Players, MP4 Players, Gaming Devices, External Hard drives, Portable Hard drives and laptop computers include a monitor, where the monitor includes a back panel that may be available for placement of a logo or general product information. These electronic devices are typically designed for mobile use and provide many computing functions similar to a desktop computer but are small and mobile enough for use on the go. One of the more popular mobile electronic devices includes the laptop computer which is essentially shaped like a large notebook where in a closed position the display screen is closed downward and not visible. In the open position, the display panel is visible by the user and the underlying keyboard on the opposite panel of the notebook computer is available for use. Laptops flip to the open position to reveal the components of the laptop. In the closed position, the typical laptop ranges in thickness from a half inch to 1.5 inches. Display panels for a laptop may range from 13 to 17 inches and the weight of a laptop is anywhere from 3 to 12 pounds. When the laptop is in an open position the display panel has a top panel on the opposite side thereof that provides a means to display the laptop manufacturer's logo or icon. The top panel remains visible to the public or any non-users while the laptop is in use. Many laptop users utilize their laptop in a public setting such as coffee shops, libraries, airports, train terminals, subways, fast food restaurants and cafeterias. When the laptop is in the open position the top panel may be utilized for display purposes, which may exclude the manufacturer's logo or name. Similar to the laptop, many of the other popular devices, such as the e-book, game players, Tablets, E-readers, E-reader/Tablets, Desktops, Phones, PDA's, Smart phones, MP3 Players, MP4 Players and Gaming Devices include a panel on the opposite side of the monitor. Further some external hard drives and portable hard drives include an available panel for display purposes.

Some owners of the electronic devices may desire to personalize or customize their device by placing stickers or other designs on an available external panel. Also, certain companies have developed designs that may be placed upon an external panel and therefore customizing the panel in a custom design for a particular user. It would be advantageous to use this panel for other purposes besides the manufacturer's logo and enable customized panels to provide a unique look and appearance of the electronic device.

### SUMMARY OF THE INVENTION

The present invention relates to an illuminated sign for various electronic devices comprising: a plurality of LED lights on a first side, where the lights provide a customized display; an adhesive backing on a second side, where the backing provides a means to attach the sign to an external panel; a means to supply power to the plurality of LED lights; and a website and/or internet connection where the user would submit design requirements prior to installing the sign The customized display may include at least one of the following; depicting text, a logo or other artistic design. In one particular embodiment, the Illuminated Sign will be powered via port of the designated device.

### BRIEF DESCRIPTION OF DRAWINGS

FIG. 1 depicts a customized external panel for a laptop computer according to the present invention.

### DETAILED DESCRIPTION

The present invention relates to an Illuminated Sign that is applied to various electronic devices. The Illuminated Sign may be placed upon the external panel of an electronic device and therefore be visible for display. In one particular embodiment, the Illuminated Sign may be placed on the opposite side of the display panel of the device. The Illuminated Sign is displayed on the reverse side of the display panel segment. The Illuminated Sign according to the present invention may use power provided by the device. The Illuminated Sign connects to a USB port and therefore provides a customized illuminated sign on the top panel of the laptop computer. In other alternative embodiments, the Illuminated Sign will be powered via port of the designated device.

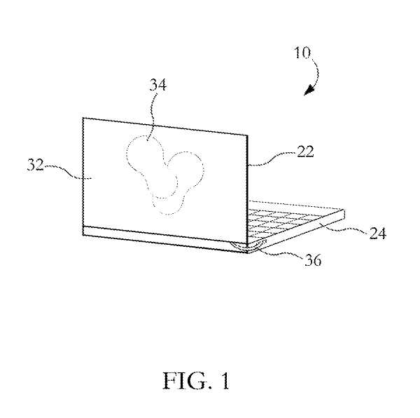

In one exemplary embodiment, a laptop computer 10 in accordance with the present invention is depicted in FIG. 1. An Illuminated Sign 32 is applied to a top Panel 22 of the laptop Computer 10. The Illuminated Sign 32 includes a very thin acrylic material with an adhesive backing wherein the adhesive backing allows for application of the Sign 32 onto the top Panel 22. After application upon the top Panel 22, the Illuminated Sign 32 is connected to a USB or designated connection via connection Cord 36. The connection Cord 36 provides a means to supply power to the Illuminated Sign 32 and therefore provide an illuminated display on the top Panel 22. The laptop Computer 10 includes both the top Panel 22 and bottom Panel 24. The bottom Panel 24 includes the traditional components of a laptop computer specifically a keyboard, tracking pad or touch pad and other functional input devices.

The Illuminated Sign 32, after being connected into the device, displays a customized design created by the user. In one exemplary embodiment, the user submits design requirements prior to installing the sign. A logo or preferably a customized design Display 34 is depicted on the Illuminated Sign 32. The user of the Illuminated Sign 32 therefore may create a unique sign depicting text, a logo or other artistic design where the Sign 32 is powered via the device through the designated connection, Cord 36, which connects to the Illuminated Sign 32. The Illuminated Sign 32 includes LED lights that illuminate the design and utilize a minimum amount of energy and therefore does not significantly impact battery life associated with the device. In the preferred embodiment, the Illuminated Sign 32 may be approximately one-eighth to one-quarter inch thick and therefore would not affect the width or depth of the laptop in a closed position. Furthermore the weight of the Illuminated Sign 32 may be minimal and therefore will not affect the actual weight of the laptop.

The Illuminated Sign 32 according to the present invention provides users with a portable, convenient and versatile means to decorate and adorn the top panel of a laptop computer. The customization features of the Illuminated Sign enable the user to create designs as desired. The Illuminated Sign provides a convenient and versatile means to decorate and customize the top panel of a laptop computer or any other external panel of any electronic devices. The invention has been shown and described in what it considers to be the most practical and preferred embodiments. It is recognized, however, that departures may be made there from within the scope of the invention and that obvious modifications will occur to a person skilled in the art.

What is claimed is:

1. An Illuminated Sign for various electronic devices comprising:
a. a plurality of LED lights on a first side, where the lights provide a customized display;
b. an adhesive backing on a second side, where the backing provides a means to attach the sign to the top panel;
c. a means to supply power to the plurality of LED lights; and
d. an internet connection, where a user submits design requirements prior to installing the sign.

2. The Illuminated Sign according to claim 1, where the customized display includes at least one of a sign depicting text, a logo or other artistic design.

3. The Illuminated Sign according to claim 1, where said input means for customizing the sign are accessible via the internet connection.

4. A method of displaying a customized display on an external panel of an electronic device comprising the steps of:
a. submitting a custom design, logo or text via website and/or internet connection prior to installing the sign;
b. adhering an Illuminated Sign on the external panel;
c. connecting the sign to a power source of the electronic device;
d. enabling connectivity between the electronic device and the sign;
